(19) United States
(12) Patent Application Publication
(10) Pub. No.: US 2008/0251113 A1
(43) Pub. Date: Oct. 16, 2008

(54) SINGLE MIRROR SOLAR CONCENTRATOR WITH EFFICIENT ELECTRICAL AND THERMAL MANAGEMENT

(76) Inventors: Stephen J. Horne, El Granada, CA (US); Peter Young, San Francisco, CA (US)

Correspondence Address: BUCKLEY, MASCHOFF & TALWALKAR LLC, 50 LOCUST AVENUE, NEW CANAAN, CT, 06840, US

(21) Appl. No.: 11/734,356

(22) Filed: Apr. 12, 2007

(51) Int. Cl. H01L 31/052

(52) U.S. Cl. 136/246

(57) ABSTRACT

An apparatus may include a housing having an inner surface and an outer surface, a mirror coupled to the inner surface of the housing, and a receiver unit coupled to the housing. The mirror is to receive direct radiation and to focus the radiation toward a localized area, and the receiver unit is to receive the radiation directly from the mirror and to convert the received radiation to electrical current.

Some aspects include a first mirror to receive a portion of direct radiation and to reflect the received portion of direct radiation toward a first localized area, a second mirror to receive a second portion of direct radiation and to reflect the received second portion of direct radiation toward a second localized area, and a receiver unit to receive the reflected portion of direct radiation directly from the first mirror and to convert the received radiation to electrical current. The receiver unit is disposed under the second mirror and is not coupled to a back side of the second mirror.

### BACKGROUND

1. Field

Some embodiments generally relate to the conversion of solar radiation to electrical current. More specifically, embodiments may relate to systems for efficient and cost-effective solar concentration and conversion.

2. Brief Description

A solar concentrator may receive solar radiation (i.e., sunlight) over a first surface area and direct the received radiation to a second, smaller, surface area. Accordingly, the intensity of the solar radiation received at the second area is greater than the intensity received at the first area. This increased intensity may allow the concentrator to convert the received solar radiation to electricity using smaller solar cell arrays than would otherwise be required.

For example, a conventional solar concentrator consists of a parabolic-shaped mirror and one or more solar cells disposed at the focal point of the mirror. During operation, the concentrator is positioned such that the one or more solar cells are between the mirror and the sun and the incoming solar radiation is parallel to a main axis of the mirror. The mirror reflects and concentrates the incoming solar radiation onto the solar cells, which convert the concentrated solar radiation to electrical current using known techniques.

The foregoing conventional systems are bulky, difficult to manufacture and often fail to provide sufficient levels of concentration. In addition, the solar cells (and any housing therefor) block a portion of the incoming solar radiation, thereby reducing an amount of solar radiation available for conversion.

U.S. Patent Application Publication No. 2006/0266408, entitled “Concentrator Solar Photovoltaic Array with Compact Tailored Imaging Power Units”, describes several types of solar concentrators utilizing unique configurations. Generally, incoming radiation is received by a primary mirror. The primary mirror reflects the received radiation toward a secondary mirror disposed between the primary mirror and the radiation source (e.g., the sun). The secondary mirror, in turn, reflects the radiation toward a photovoltaic cell, which converts the concentrated radiation to electrical current.

The foregoing arrangements provide improved concentration ratios, but may be difficult to manufacture due to the required alignment of the primary mirror, the secondary mirror and the solar cell. Moreover, the additional reflection at the secondary mirror may result in additional energy losses in the form of heat. The secondary mirror may also reduce an amount of incoming radiation available for conversion by preventing some of the radiation from reaching the primary mirror.

U.S. Patent Application Publication No. 2005/0022858 and U.S. Pat. Nos. 4,153,474, 5,180,441, and 5,344,496 describe another general type of solar concentrator. The solar concentrators described therein include rows of curved mirrors oriented in a single direction to accept incoming radiation. A solar cell or line of solar cells is mounted to the back (i.e., non-reflective) side of each mirror. Accordingly, each mirror receives incoming radiation and reflects the incoming radiation to the solar cell or line of solar cells mounted to the back of an adjacent mirror.

These solar concentrators present several difficulties. The reflective surface of each mirror must be aligned with the reflective surface of each other mirror, and the solar cell or cells mounted on each mirror must be aligned with the mirror from which the cell(s) will receive radiation. Moreover, since the solar cells are rather inaccessible within the rows of mirrors, it is difficult to dissipate heat from the solar cells and/or to extract electrical current generated thereby.

### SUMMARY

To address at least the foregoing, some embodiments provide an apparatus including a housing having an inner surface and an outer surface, a mirror coupled to the inner surface of the housing, and a receiver unit coupled to the housing. The mirror is to receive direct radiation and to focus the radiation toward a localized area, and the receiver unit is to receive the radiation directly from the mirror and to convert the received radiation to electrical current.

In further aspects, the receiver unit includes a photovoltaic cell and an optical element to receive the reflected radiation from the mirror and to direct the received radiation toward the photovoltaic cell. A portion of the optical element is co-located with the localized area. Some aspects include a second mirror coupled to the inner surface of the housing and a second receiver unit coupled to the housing. The second mirror is to receive second direct radiation and to focus the received second direct radiation toward a second localized area, and the second receiver unit to receive the second radiation directly from the second mirror and to convert the received second radiation to electrical current.

According to some aspects, an apparatus further includes a second housing comprising a second inner surface and a second outer surface, a second mirror coupled to the second inner surface of the second housing, and a second receiver unit coupled to the second housing. The second mirror is to receive second direct radiation and to focus the received second direct radiation toward a second localized area, and the second receiver unit is to receive the second radiation directly from the second mirror and to convert the received second radiation to electrical current. A portion of the outer surface of the housing opposite the receiver unit is not in contact with the second outer surface of the second housing. The second mirror may prevent the second direct radiation from reaching the receiver unit.

In another aspect, an apparatus includes a first mirror to receive a portion of direct radiation and to reflect the received portion of direct radiation toward a first localized area, a second mirror to receive a second portion of direct radiation and to reflect the received second portion of direct radiation toward a second localized area, and a receiver unit to receive the reflected portion of direct radiation directly from the first mirror and to convert the received radiation to electrical current. The receiver unit is disposed under the second mirror and is not coupled to a back side of the second mirror.

Further to the foregoing aspect, also included may be a first housing comprising a first inner surface and a first outer surface, and a second housing comprising a second inner surface and a second outer surface. The first mirror is coupled to a first portion of the first inner surface, the receiver unit is coupled to a second portion of the first inner surface, the second mirror is coupled to a first portion of the second inner surface, and a portion of the outer surface of the first housing opposite the second portion of the first inner surface is not in contact with the second outer surface of the second housing.

Some aspects also or alternatively provide a substantially planar surface, and the portion of the direct radiation is to pass normal to the substantially planar surface before reaching the first mirror. Moreover, none of the reflected portion of the direct radiation is reflected toward the substantially planar surface.

The claims are not limited to the disclosed embodiments, however, as those in the art can readily adapt the description herein to create other embodiments and applications.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a perspective view of an apparatus including a first mirror and a second mirror according to some embodiments.

FIG. 2 is a cross-sectional end view of the FIG. 1 apparatus according to some embodiments.

FIG. 3 is an exploded view of a receiver unit of an apparatus according to some embodiments.

FIGS. 4A and 4B illustrate a mirror geometry according to some embodiments.

FIGS. 5A and 5B are cross-sectional end views illustrating off-axis operation of an apparatus according to some embodiments.

FIGS. 6A and 6B are perspective views of apparatuses including mirrors integrated with housings according to some embodiments.

FIG. 7 is a perspective view of an integral mirror and optical element according to some embodiments.

FIG. 8 is a perspective view of an array of radiation-collecting mirrors according to some embodiments.

FIG. 9 is a perspective view of an array of radiation-collecting mirrors according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

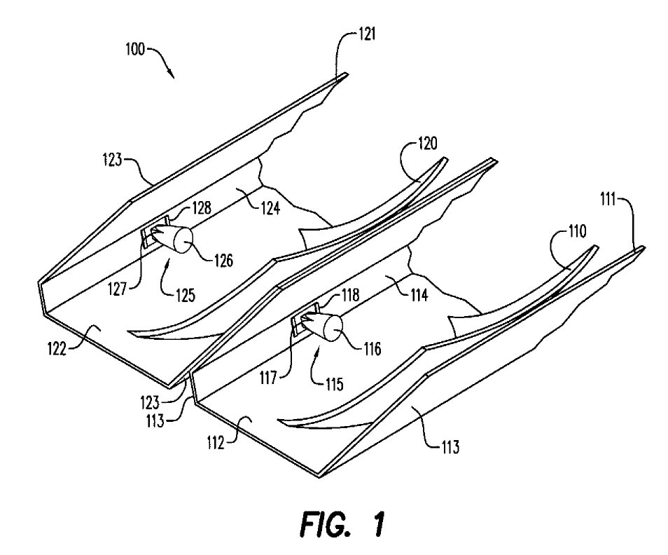

FIG. 1 is a perspective view of apparatus 100 according to some embodiments. Apparatus 100 may comprise a concentrating solar power unit. Generally, apparatus 100 may operate to receive incoming solar radiation, to concentrate the radiation, and to convert the concentrated radiation to electrical current.

Apparatus 100 includes mirror 110 and mirror 120. Mirror 110 and mirror 120 receive radiation from the sun and focus the radiation toward a respective localized area. Mirror 110 and mirror 120 may comprise any suitable shape, size, composition and reflective material that is or becomes known, and need not be identical to one another. One or both of mirror 110 and mirror 120 may be asymmetric with respect to at least one axis.

According to some embodiments, mirror 110 and mirror 120 comprise surface mirrors using a silver-based reflective coating with or without a passivation layer, and may be slump-formed from low iron soda-lime or borosilicate glass. The reflective coating may be selected to provide a desired spectral response to the wavelengths of solar radiation to be collected, concentrated and converted to electricity by apparatus 100. Specific geometric shapes of mirror 110 and mirror 120 according to some embodiments will be discussed below.

Mirror 110 is coupled to inner surface 112 of housing 111. Similarly, mirror 120 is coupled to inner surface 122 of housing 121. Mirror 110 and mirror 120 may be directly attached to their respective housing by compression, welding, or adhesive bonding, or may be attached to an interposer that is in turn attached to the housing. Housing 111 and housing 121 may comprise sheet metal or any other combination of materials. The composition of housing 111 and housing 121 may be selected to provide heat dissipation as well as structural stability to the elements of apparatus 100. In some embodiments, housing 111 and housing 121 comprise aluminum.

Receiver unit 115 is coupled to housing 111. According to FIG. 1, receiver unit 115 is coupled to inner surface 114 of housing 111, but embodiments are not limited thereto. Receiver unit 115 receives focused radiation directly from mirror 110 and converts the received radiation to electrical current. In this regard, at least a portion of receiver unit 115 may be co-located with the localized area toward which mirror 110 focuses received radiation.

Receiver unit 115 includes optical element 116, photovoltaic cell 117 and circuit board 118. Optical element 116 may receive reflected radiation directly from mirror 110 and direct the received radiation toward photovoltaic cell 117. Optical element 116 may comprise any suitable optical material, and may utilize total internal reflection to direct the received radiation. A portion of optical element 116 may be co-located with the localized area toward which mirror 110 directs incoming radiation.

Photovoltaic cell 117 may comprise one or more solar cells (e.g., a III-V cell, II-VI cell, etc.). Specifically, cell 117 may operate to receive photons and generate electrical charge carriers in response thereto. Cell 117 may comprise any number of active, dielectric and metallization layers, and may be fabricated using any suitable methods that are or become known.

Circuit board 118 is coupled to photovoltaic cell 117 and to inner surface 114. Circuit board 118 may provide electrical interconnections between photovoltaic cell 117 and unshown control and/or monitoring elements, and may carry electrical current generated by photovoltaic cell 117. The electrical current may be combined with electrical current generated by other photovoltaic cells of apparatus 100.

Receiver unit 125 may share a similar construction and a similar function relationship as described above with respect to receiver unit 115. Embodiments are not, however, limited to the illustrated and described arrangement of receiver unit 115.

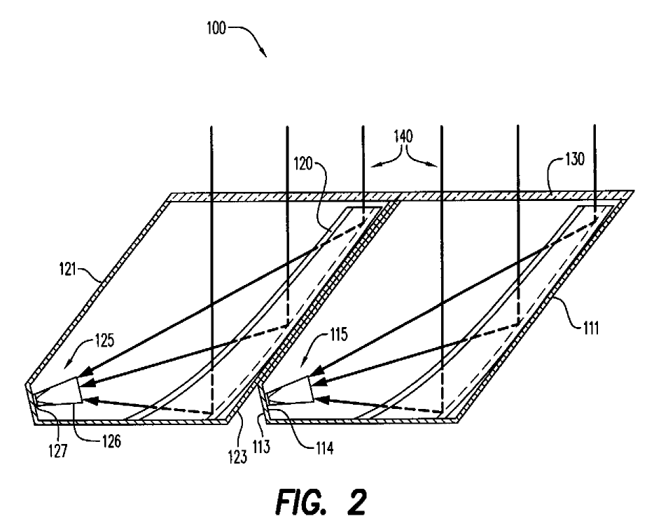

FIG. 2 is a cross-sectional end view of apparatus 100 according to some embodiments. FIG. 2 illustrates operation of apparatus 100 according to some embodiments.

Apparatus 100 of FIG. 2 includes protective front surface 130, a representation of which was omitted from FIG. 1 for clarity. Surface 130 may comprise a substantially planar window or cover glazing to pass incident radiation. Surface 130 may be composed more than one material including but not limited to glass, an anti-reflective coating, transparent structural layers, etc. Substantially planar surface 130 is supported by respective walls of housing 111 and housing 121.

In operation, surface 130 receives radiation 140. Apparatus 100 is positioned such that radiation 140 is substantially normal to substantially planar surface 130. Surface 130 passes a first portion of radiation 140 to mirror 110 and a second portion of radiation 140 to mirror 120. Mirror 110 and mirror 120 receive the respective first and second portions and reflect the radiation toward a respective localized area. Receiver units 115 and 125 receive the reflected radiation directly from mirrors 110 and 120, respectively, and convert the received radiation to electrical current.

As illustrated in FIG. 2, none of the radiation reflected by mirror 110 or mirror 120 is reflected back toward substantially planar surface 130. According to some embodiments, the foregoing feature allows receiver units 115 and 125 to be placed at locations which facilitate the extraction of generated heat and/or electrical current.

Receiver unit 115 disposed under mirror 120. Moreover, receiver unit 115 is not coupled to a backside of mirror 120. Second mirror 120 may therefore, in some embodiments, prevent radiation 140 from reaching receiver unit 115. In addition, the backside of mirror 120 need not be aligned with the localized area to which mirror 110 reflects radiation 140.

FIG. 2 also illustrates reception of a substantial percentage of normal radiation 140 by mirror 110 and mirror 120. In this regard, a portion of the top edge of mirror 120 may be positioned between a source of radiation 140 (e.g., the sun) and a portion of the bottom edge of mirror 110. The actual percentage of radiation 140 that is received by mirrors 110 and 120 may vary across embodiments and may depend upon one or more of the shape and size of mirrors 110 and 120, the angle of mirrors 110 and 120 with respect to the bottom of their respective housings, and the degree of overlap between mirrors 110 and 120 in a plane perpendicular to the FIG. 2 drawing sheet.

Receiver unit 115 is coupled to a portion of inner surface 114 of housing 111 as shown in FIG. 1 and FIG. 2. As also shown, a portion of outer surface 113 of housing 111 is opposite to the portion of inner surface 114 to which receiver unit 115 is coupled. This portion of outer surface 113, in the illustrated embodiment, does not contact outer surface 123 of housing 121. More specifically, this portion of outer surface 113 and the adjacent portion of outer surface 123 define a notch (or channel) between housing 111 and housing 121.

The above-described notch may facilitate access to a backside of cell 117 and/or may facilitate the extraction of generated heat and/or electrical current from cell 117. In some embodiments, structures for mounting or otherwise supporting apparatus 100 may be coupled to the notch. A shape and a size of the notch are not limited to the illustrated embodiments.

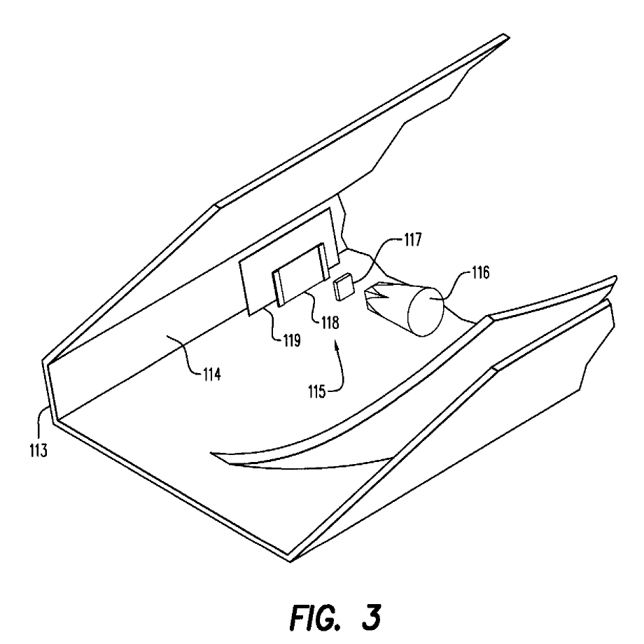

FIG. 3 is a close-up exploded perspective view of receiver unit 115 according to some embodiments. Receiver unit 115 of FIG. 3 is identical to that described with respect to FIG. 1 with the exception of heat sink 118. Heat sink 118 may assist in dispersing heat generated by photovoltaic cell 117 and/or resulting from the radiation concentrated thereon. Heat sink 118 is shown coupled to inner surface 114, but some embodiments may exhibit alternative arrangements. For example, heat sink 118 may be coupled to outer surface 113 of housing 111 opposite from cell 117, or may be eliminated altogether.

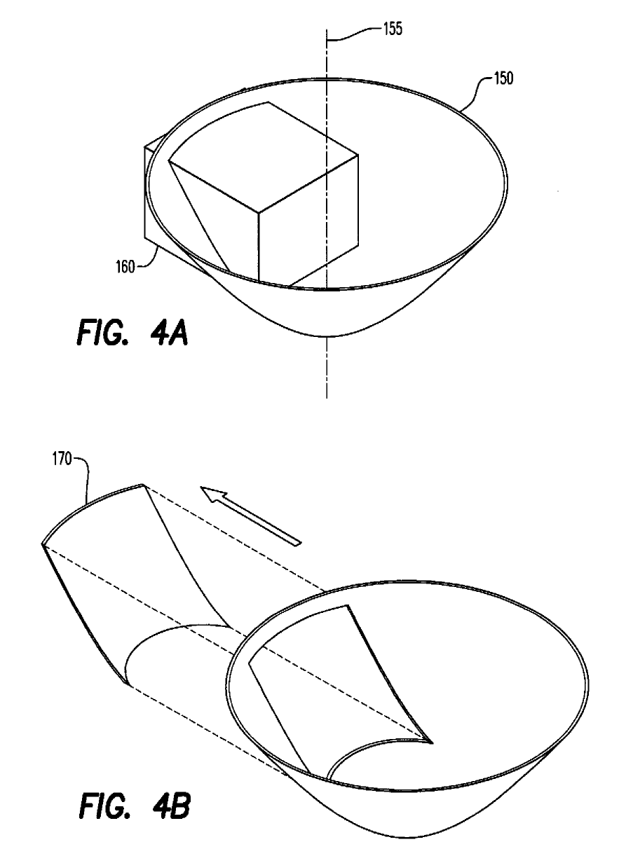

FIGS. 4A and 4B illustrate a geometric conception of mirror 110 according to some embodiments. FIG. 4A shows paraboloid 150 having axis 155. A shape of paraboloid 150 may be governed by any equation that is deemed suitable. Rectangular solid 160 intersects an off-axis portion of paraboloid 160. Rectangular solid 160 may also exhibit any suitable dimensions.

Shape 170 of FIG. 4B is the geometric intersection between paraboloid 150 and rectangular solid 160 depicted in FIG. 4A. A shape of mirror 110 and/or mirror 120 may be identical to shape 170 according to some embodiments. Embodiments are not limited to shape 170 or to the intersection between an off-axis portion of a paraboloid and a rectangular solid. In some embodiments, a shape of mirror 110 and/or mirror 120 comprises the intersection between a non-axially symmetric solid and a rectangular solid.

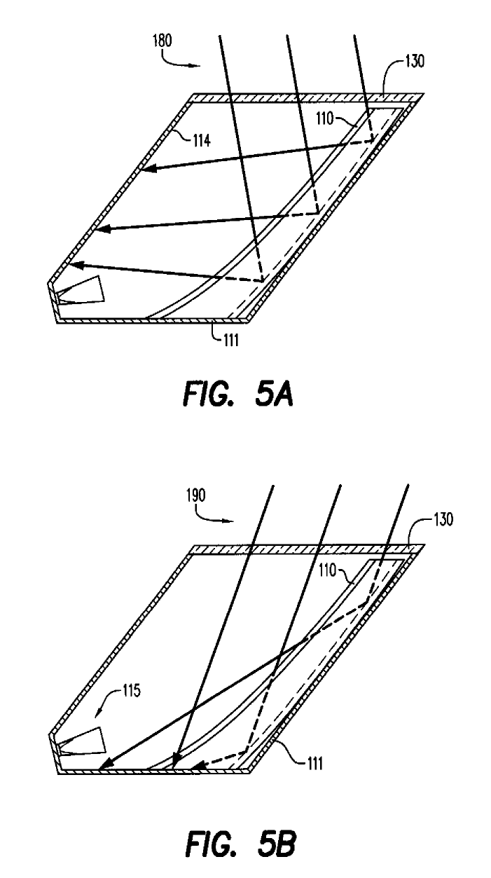

FIG. 5A depicts off-axis operation according to some embodiments. Incoming radiation 180 is not substantially normal to substantially planar surface 130. Due to the trajectory of incoming radiation 180, radiation 180 is reflected by mirror 110 toward inner surface 114 of housing 111. Housing 111 therefore absorbs radiation 180 and any associated heat. Since radiation 180 is not substantially concentrated by mirror 110, the heat absorbed by housing 111 might not be significantly intense.

FIG. 5B also depicts off-axis operation according to some embodiments. Incoming radiation 190 is not substantially normal to substantially planar surface 130, and is reflected by mirror 110 toward the bottom of housing 111. Housing 111 again absorbs radiation 190 and any associated heat, which is diffuse in comparison to heat absorbed by receiver unit 115 during on-axis operation. Housing 111 may radiate some of the heat through its bottom.

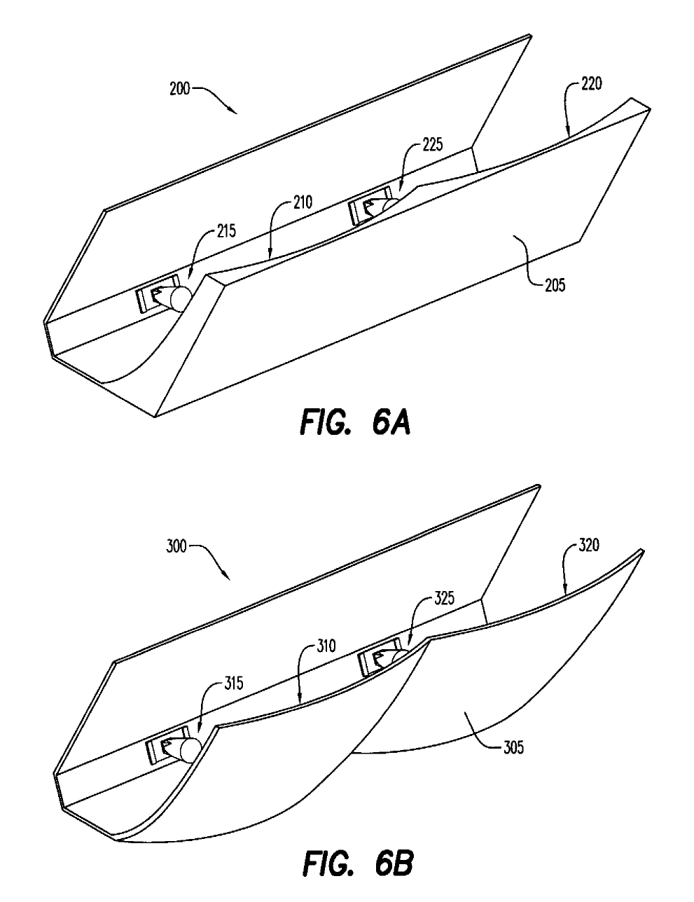

FIG. 6A is a perspective view of apparatus 200 according to some embodiments. Apparatus 200 may operate to receive incoming solar radiation, to concentrate the radiation, and to convert the concentrated radiation to electrical current.

Apparatus 200 includes housing 205, mirror 210, mirror 220, and receiver units 215 and 225, Mirrors 210 and 220 receive respective portions of incoming radiation and reflect the radiation toward respective localized areas. Receiver units 215 and 225 may be configured similarly to receiver unit 115 in order to receive radiation from mirrors 210 and 220 and to convert the radiation to electrical current.

Mirrors 210 and 220 are integral with housing 205. According to some embodiments, an inner surface of housing 205 defines depressions onto which reflective material of mirrors 210 and 220 is deposited. The depressions may be stamped into housing 220, molded into housing 220 during fabrication thereof, or otherwise defined. Embodiments of the foregoing may facilitate alignment of mirrors 210 and 220 with receiver units 215 and 225 and/or may decrease fabrication costs.

FIG. 6B is a perspective view of apparatus 300 according to some embodiments. Apparatus 300 may also operate to receive incoming solar radiation, to concentrate the radiation, and to convert the concentrated radiation to electrical current.

Apparatus 300 includes housing 305, mirror 310, mirror 320, receiver unit 315 and receiver unit 325. Mirror 310, mirror 320, receiver unit 315 and receiver unit 325 may operate in accordance with any of the embodiments described herein. Receiver unit 315 and receiver unit 325 may be constructed in accordance with any of such embodiments as well.

Mirrors 310 and 320 are integral with housing 305 as described with respect to FIG. 6A. However, an outer surface and an inner surface of housing 305 are curved to provide the desired shape of mirror 310 and mirror 320. According to some embodiments, reflective material of mirrors 310 and 320 is deposited on the curved inner surface of housing 305.

Embodiments of apparatus 200 and apparatus 300 may facilitate alignment of mirrors with respective receiver units and/or may decrease fabrication costs. Either of apparatus 200 and apparatus 300 may include additional identical housings arranged to create a two-dimensional array of mirror/receiver unit combinations as suggested by FIGS. 1 and 2.

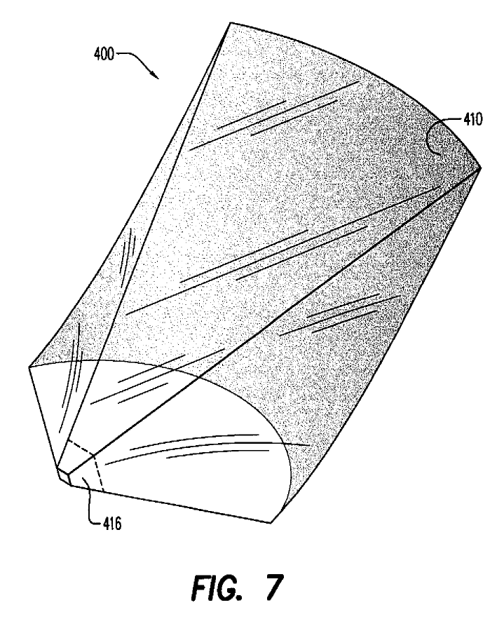

FIG. 7 provides a perspective view of integral element 400 including mirror 410 and optical element 416. Integral element 400 may be substituted for any mirror/optical element combination of apparatus 100. Integral element 400 may therefore operate to receive radiation from the sun, reflect the radiation using mirror 410 toward a respective localized area, and direct the reflected radiation toward a photovoltaic cell (not shown).

Integral element 400 may be composed of transparent material and may be press-molded or otherwise fabricated. Mirror 410 may comprise reflective material deposited on the transparent material as shown. Integral element 400 may provide accurate and fixed alignment between mirror 410 and optical element 416 according to some embodiments.

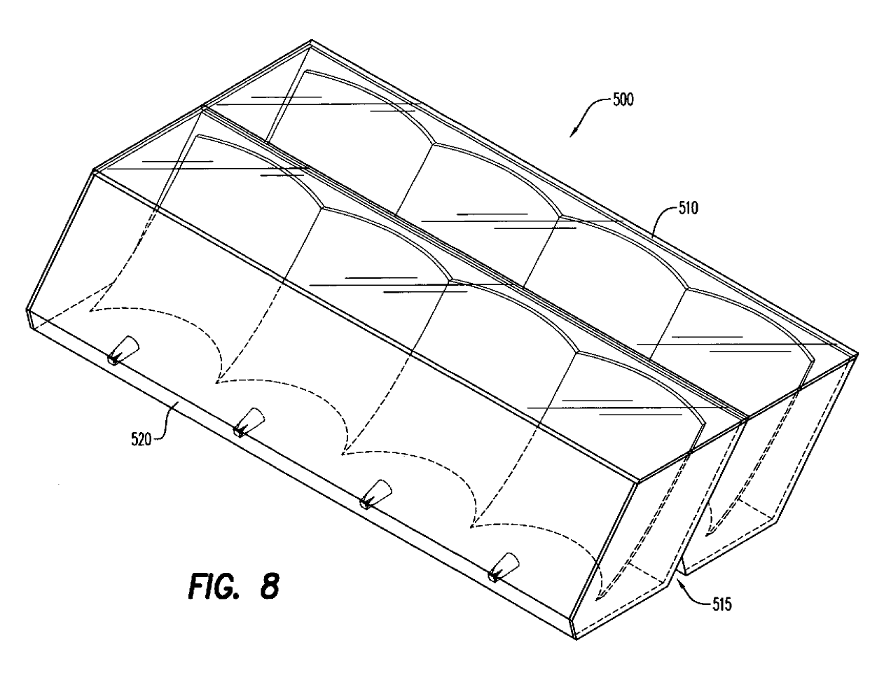

FIG. 8 is a perspective view of array 500 according to some embodiments. Array 500 comprises housing 510 and housing 520, each including four mirror/receiver unit combinations which may comprise any of the embodiments described herein. Apparatus 500 may comprise any number of housings, and each housing may comprise any number of mirror/receiver unit combinations.

Apparatus 500 may conform to the end cross-sectional view of FIG. 2. In this regard, housing 510 and housing 520 define notch 515 therebetween to facilitate heat dissipation and access to the receiver units of housing 510. A portion of the top edges of the mirrors of housing 520 may also be positioned between a radiation source and a portion of the bottom edges of the mirrors of housing 510 to increase the amount of radiation concentrated by apparatus 500. Moreover, the mirrors of housing 520 may prevent some (i.e., non-concentrated) incoming radiation from reaching the receiver units of housing 510.

FIG. 8 also shows contact between adjacent right and left edges of the illustrated mirrors. Such an arrangement may increase an amount of concentrated light (and electrical current subsequently converted therefrom) generated by apparatus 500 by preventing incoming light from passing between two mirrors to the bottom surface of a housing.

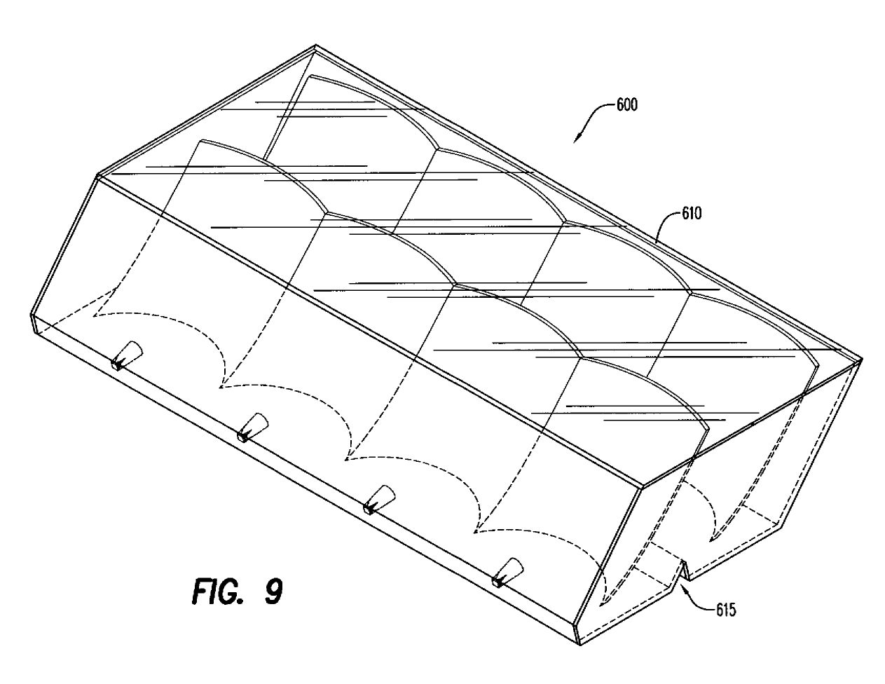

FIG. 9 is a perspective view of array 600 according to some embodiments. Array 600 comprises single housing 610, which includes two rows of four mirror/receiver unit combinations as described herein. Some embodiments may comprise any number of rows of and number of mirror/receiver unit combinations in each row.

Housing 610 does not include a wall between adjacent rows as shown in FIG. 8. Nevertheless, housing 610 defines notch 615 to facilitate heat dissipation and access to the receiver units of housing 610. In addition, a portion of the top edges of the front mirrors may be positioned between a radiation source and a portion of the bottom edges of the rear mirrors, and the front mirrors may prevent some incoming radiation from reaching the receiver units of the rear mirrors.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. An apparatus comprising:
a housing comprising an inner surface and an outer surface;
a mirror coupled to the inner surface of the housing, the mirror to receive direct radiation and to focus the radiation toward a localized area; and
a receiver unit coupled to the housing, the receiver unit to receive the radiation directly from the mirror and to convert the received radiation to electrical current.

2. An apparatus according to claim 1, wherein the receiver unit comprises:
a photovoltaic cell coupled to the housing.

3. An apparatus according to claim 1, wherein the receiver unit comprises:
a photovoltaic cell; and
an optical element to receive the reflected radiation from the mirror and to direct the received radiation toward the photovoltaic cell, a portion of the optical element being co-located with the localized area.

4. An apparatus according to claim 3, wherein the receiver unit further comprises:
a heat sink coupled to the photovoltaic cell and to the housing.

5. An apparatus according to claim 3, wherein the mirror and the optical element are components of an integral element, and
wherein the mirror comprises a reflective material disposed on the integral element.

6. An apparatus according to claim 1, wherein the mirror comprises:
a shape comprising an intersection between a rectangular solid and an off-axis portion of a paraboloid.

7. An apparatus according to claim 1, wherein the mirror comprises-a shape comprising an intersection between a rectangular solid and a non-axially symmetric solid.

8. An apparatus according to claim 1, further comprising:
a second mirror coupled to the inner surface of the housing, to receive second direct radiation, and to focus the received second direct radiation toward a second localized area; and
a second receiver unit coupled to the housing, the second receiver unit to receive the second radiation directly from the second mirror and to convert the received second radiation to electrical current.

9. An apparatus according to claim 8, wherein the second receiver unit comprises:
a second photovoltaic cell; and
a second optical element to receive the second radiation directly from the second mirror and to direct the received second radiation toward the second photovoltaic cell, a portion of the second optical element being co-located with the second localized area.

10. An apparatus according to claim 8, wherein a left edge of the second mirror is in contact with a right edge of the mirror.

11. An apparatus according to claim 1, further comprising:
a second housing comprising a second inner surface and a second outer surface;
a second mirror coupled to the second inner surface of the second housing, to receive second direct radiation, and to focus the received second direct radiation toward a second localized area; and
a second receiver unit coupled to the second housing, the second receiver unit to receive the second radiation directly from the second mirror and to convert the received second radiation to electrical current,
wherein a portion of the outer surface of the housing opposite the receiver unit is not in contact with the second outer surface of the second housing.

12. An apparatus according to claim 11,
wherein the second mirror prevents the second direct radiation from reaching the receiver unit.

13. An apparatus according to claim 12,
wherein a top edge of the second mirror is disposed between the sun and a bottom edge of the mirror.

14. An apparatus according to claim 1, wherein the mirror comprises:
a reflective material disposed on the inner surface of the housing.

15. A method comprising:
receiving direct radiation at a mirror coupled to an inner surface of a housing;
focusing the radiation toward a localized area using the mirror;
receiving the radiation directly from the mirror at a receiver unit coupled to the housing; and
converting the received radiation to electrical current using the receiver unit.

16. A method according to claim 15, further comprising:
receiving second direct radiation at a second mirror coupled to the inner surface of the housing;
focusing the received second direct radiation toward a second localized area;
receiving the second radiation directly from the second mirror at a second receiver unit coupled to the housing; and
converting the received second radiation to electrical current using the second receiver unit.

17. An apparatus comprising:
a first mirror to receive a portion of direct radiation and to reflect the received portion of direct radiation toward a first localized area;
a second mirror to receive a second portion of direct radiation and to reflect the received second portion of direct radiation toward a second localized area; and
a receiver unit to receive the reflected portion of direct radiation directly from the first mirror and to convert the received radiation to electrical current,
wherein the receiver unit is disposed under the second mirror and is not coupled to a back side of the second minor.

18. An apparatus according to claim 17, wherein the receiver unit comprises:
a photovoltaic cell to convert the received radiation to electrical current;
an optical element to receive the reflected portion of direct radiation and to direct the received radiation toward the photovoltaic cell,
wherein a portion of the optical element is co-located with the first localized area.

19. An apparatus according to claim 18, wherein the first mirror and the optical element are components of an integral element, and
wherein the first mirror comprises a reflective material disposed on the integral element.

20. An apparatus according to claim 17, wherein the first mirror comprises:
a shape comprising an intersection between a rectangular solid and an off-axis portion of a paraboloid.

21. An apparatus according to claim 17, wherein the first mirror comprises:
a shape comprising an intersection between a rectangular solid and a non-axially symmetric solid.

22. An apparatus according to claim 17, further comprising:
a first housing comprising a first inner surface and a first outer surface; and
a second housing comprising a second inner surface and a second outer surface,
wherein the first mirror is coupled to a first portion of the first inner surface,
wherein the receiver unit is coupled to a second portion of the first inner surface,
wherein the second mirror is coupled to a first portion of the second inner surface, and
wherein a portion of the outer surface of the first housing opposite the second portion of the first inner surface is not in contact with the second outer surface of the second housing.

23. An apparatus according to claim 17,
wherein the second mirror prevents the second portion of direct radiation from reaching the receiver unit.

24. An apparatus according to claim 17, further comprising:
a substantially planar surface, the portion of the direct radiation to pass normal to the substantially planar surface before reaching the first mirror,
wherein none of the reflected portion of the direct radiation is reflected toward the substantially planar surface.
